(19) United States
(12) Patent Application Publication
(10) Pub. No.: US 2006/0134917 A1
(43) Pub. Date: Jun. 22, 2006

(54) Reduction of etch mask feature critical dimensions

(75) Inventors: Zhisong Huang, Fremont, CA (US); S.M. Reza Sadjadi, Saratoga, CA (US); Jeffrey Marks, San Jose, CA (US)

Correspondence Address: BEYER WEAVER & THOMAS LLP, P.O. BOX 70250, OAKLAND, CA, 94612-0250, US

(73) Assignee: Lam Research Corporation

(21) Appl. No.: 11/016,455

(22) Filed: Dec. 16, 2004

(51) Int. Cl. H01L 21/4757; C23F 1/00

(52) U.S. Cl. 438/694; 156/345.24; 156/345.33; 438/696

(57) ABSTRACT

A method for forming features in an etch layer in an etch stack with an etch mask over the etch layer, wherein the etch mask has etch mask features with sidewalls, where the etch mask features have a first critical dimension, is provided. A cyclical critical dimension reduction is performed to form deposition layer features with a second critical dimension, which is less than the first critical dimension. Each cycle, comprises a depositing phase for depositing a deposition layer over the exposed surfaces, including the vertical sidewalls, of the etch mask features and an etching phase for etching back the deposition layer leaving a selective deposition on the vertical sidewalls. Features are etched into the etch layer, wherein the etch layer features have a third critical dimension, which is less than the first critical dimension.

### BACKGROUND OF THE INVENTION

The present invention relates to the formation of semiconductor devices.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed. Thereafter, the wafer is etched to remove the underlying material from the areas that are no longer protected by the photoresist material, and thereby define the desired features in the wafer.

Various generations of photoresist are known. Deep ultra violet (DUV) photoresist is exposed by 248 nm light. To facilitate understanding, FIG. 1A is a schematic cross-sectional view of a layer 108 over a substrate 104, with a patterned photoresist layer 112, over an ARL (Anti-reflective layer) 110 over the layer 108 to be etched forming a stack 100. The photoresist pattern has a critical dimension (CD), which may be the width 116 of the smallest feature. Presently, for 248 nm photoresist a typical CD for the photoresist may be 230-250 nm using conventional processes. Due to optical properties dependent on wavelength, photoresist exposed by longer wavelength light has larger theoretical minimal critical dimensions.

A feature 120 may then be etched through the photoresist pattern, as shown in FIG. 1B. Ideally, the CD of the feature (the width of the feature) is equal to the CD 116 of the feature in the photoresist 112. In practice, the CD of the feature 116 may be larger than the CD of the photoresist 112 due to faceting, erosion of the photoresist, or undercutting. The feature may also be tapered, where the CD of the feature is at least as great as the CD of the photoresist, but where the feature tapers to have a smaller width near the feature bottom. Such tapering may provide unreliable features.

In order to provide features with smaller CD, features formed using shorter wavelength light are being pursued. 193 nm photoresist is exposed by 193 nm light. Using phase shift reticles and other technology, a 90-100 nm CD photoresist pattern may be formed, using 193 nm photoresist. This would be able to provide a feature with a CD of 90-100 nm. 157 nm photoresist is exposed by 157 nm light. Using phase shift reticles and other technology sub 90 nm CD photoresist patterns may be formed. This would be able to provide a feature with a sub 90 nm CD.

The use of shorter wavelength photoresists may provide additional problems over photoresists using longer wavelengths. To obtain CD's close to the theoretical limit the lithography apparatus should be more precise, which would require more expensive lithography equipment. Presently 193 nm photoresist and 157 nm photoresist may not have selectivities as high as longer wavelength photoresists and may more easily deform under plasma etch conditions.

In the etching of conductive layers, such as in the formation of memory devices, it is desirable to increase device density without diminishing performance.

### SUMMARY OF THE INVENTION

To achieve the foregoing and in accordance with the purpose of the present invention a method for forming features in an etch layer in an etch stack with an etch mask over the etch layer, wherein the etch mask has etch mask features with sidewalls, where the etch mask features have a first critical dimension, is provided. A cyclical critical dimension reduction is performed to form deposition layer features with a second critical dimension, which is less than the first critical dimension. Each cycle, comprises a depositing phase for depositing a deposition layer over the exposed surfaces, including the vertical sidewalls, of the etch mask features and an etching phase for etching back the deposition layer leaving a selective deposition on the vertical sidewalls. Features are etched into the etch layer, wherein the etch layer features have a third critical dimension, which is less than the first critical dimension.

In another embodiment of the invention a method for forming a feature in an etch layer is provided. An etch stack with an etch layer is placed into an etch chamber, wherein an etch mask with etch mask features with sidewalls is over the etch layer, where the etch mask features have a first critical dimension. For at least two cycles a cyclical critical dimension reduction is performed to form deposition layer features with a second critical dimension, which is less than the first critical dimension, within the etch chamber. Each cycle comprises a depositing phase for depositing a deposition layer over the sidewalls of the etch mask features and an etching phase for etching back the deposition layer. Features are etched into the etch layer within the etch chamber, wherein the etch layer features have a third critical dimension, which is less than the first critical dimension.

In another embodiment of the invention, an apparatus for forming a features in an etch layer is provided, where the layer is supported by a substrate and where the etch layer is covered by an etch mask with mask features with a first CD. A plasma processing chamber comprises a chamber wall forming a plasma processing chamber enclosure, a substrate support for supporting a substrate within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. A gas source is in fluid connection with the gas inlet. A controller is controllably connected to the gas source and the at least one electrode and comprises at least one processor and computer readable media. The computer readable media comprises computer readable code for providing for at least five cycles a cyclical critical dimension reduction process to form deposition layer features with a second critical dimension, computer readable code for providing a flow of an etchant gas to the plasma processing chamber after completion of the at least five cycles of the cyclical critical dimension reduction process, and computer readable code for etching features in the etch layer, using the etchant gas wherein the features in the layer have a third critical dimension. The computer readable code for providing for at least five cycles a cyclical critical dimension reduction process to form deposition layer features with a second critical dimension, comprises computer readable code for providing a flow of a deposition gas to the plasma processing chamber enclosure, computer readable code for stopping the flow of the deposition gas to the plasma processing chamber enclosure, computer readable code for providing a flow of an etch phase gas to the plasma processing chamber enclosure after the flow of the first deposition gas is stopped, and computer readable code for stopping the flow of the etch phase gas to the plasma processing chamber enclosure.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIGS. 1A-B are schematic cross-sectional views of a stack etched according to the prior art.

FIG. 2 is a high level flow chart of a process that may be used in an embodiment of the invention.

FIGS. 3A-D are schematic cross-sectional views of a stack processed according to an embodiment of the invention.

FIGS. 4A-F are schematic cross-sectional views of a stack processed according to an example of the invention.

FIG. 5 is a schematic view of a plasma processing chamber that may be used in practicing the invention.

FIGS. 6A-B illustrate a computer system, which is suitable for implementing a controller used in embodiments of the present invention.

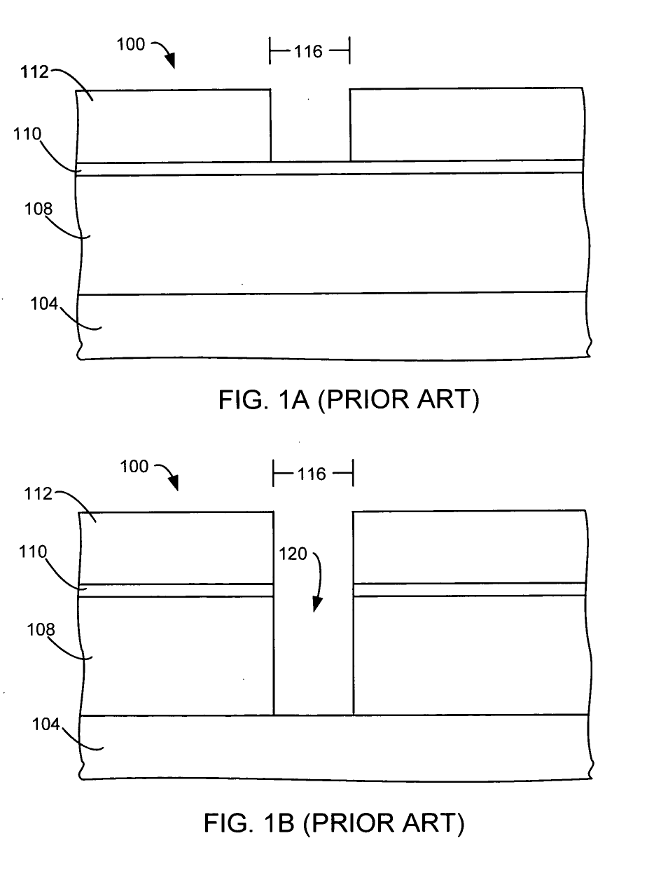

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

The invention provides features with small critical dimensions (CD). More specifically, the invention provides a features with CD's that are less than the CD of the patterned mask used to etch the feature.

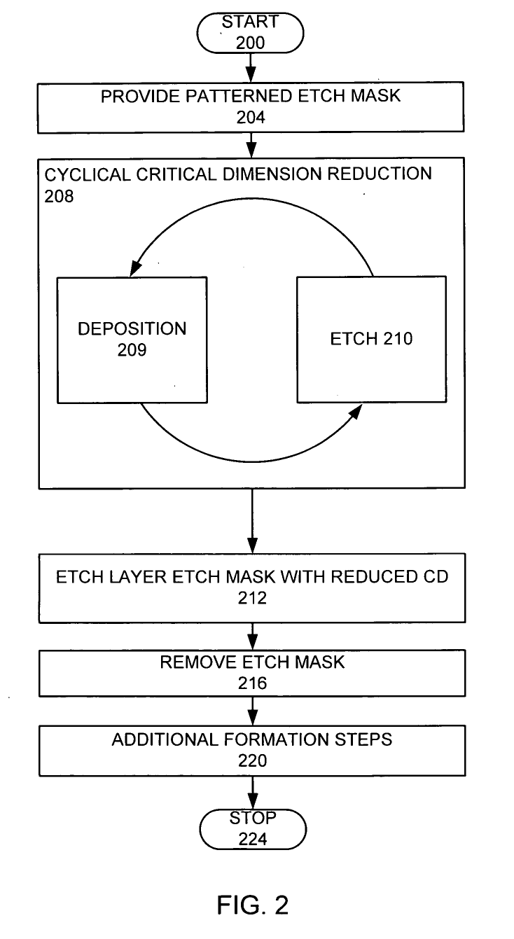

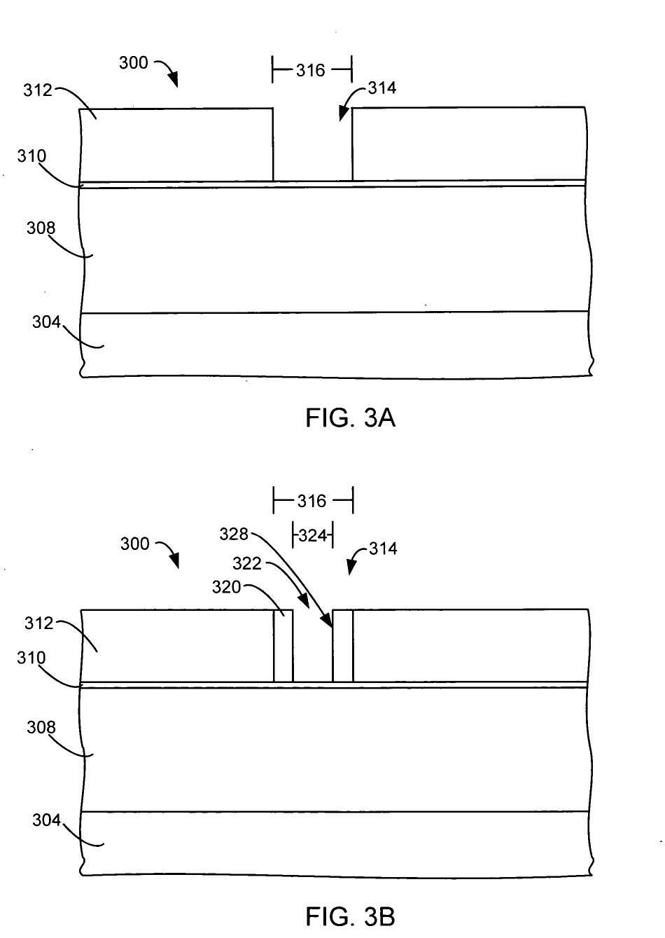

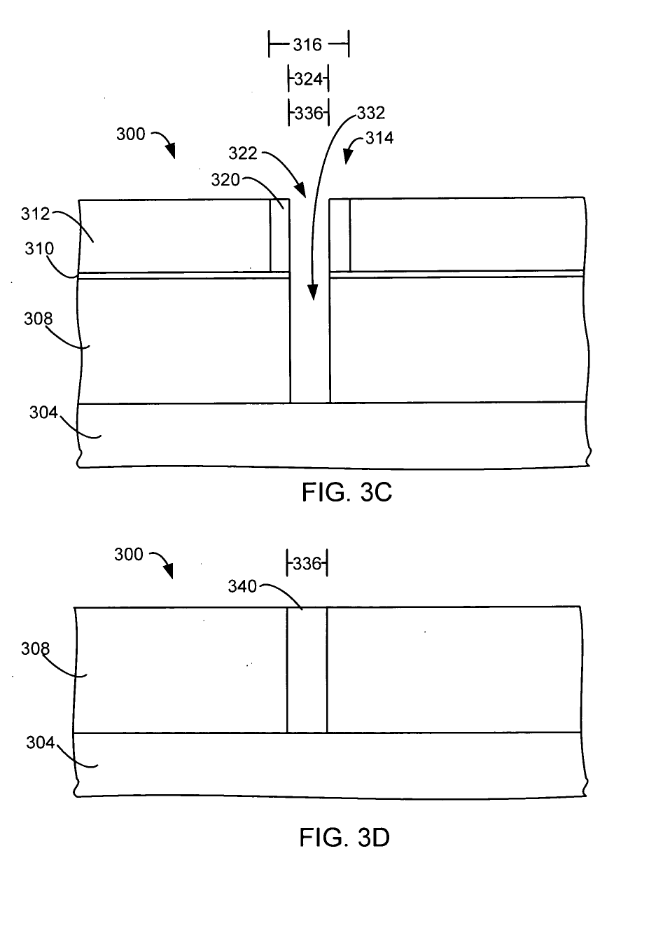

To facilitate understanding, FIG. 2 is a high level flow chart of a process that may be used in an embodiment of the invention. A patterned etch mask is provided (step 204). Examples of such a patterned etch mask are patterned photoresist masks and hard masks, such as a silicon hardmask or an amorphous carbon hardmask. FIG. 3A is a schematic cross-sectional view of an etch layer 308 over a substrate 304. A patterned etch mask 312 with a feature 314 is over an ARL 310, over the etch layer 308, over a substrate 304, which forms a stack 300. The etch mask has a mask feature critical dimension (CD), which may be the widest part of the width 316 of the smallest possible feature.

A cyclical critical dimension reduction is performed to reduced the CD (step 208). The cyclical critical reduction process comprises at least two steps of depositing a layer over the sidewalls of the etch mask feature 314 (step 209) and then etching back the deposition layer (step 210). FIG. 3B is a schematic cross-sectional view of the patterned etch mask 312 with a layer 320, formed by the cyclical critical dimension reduction, deposited over the sidewalls of the feature 314. The deposition layer 320 forms a deposition layer feature 322 within the mask feature 314, where the deposition layer feature 322 has a reduced CD 324 that is less than the CD 316 of the mask feature 314.

Preferably, the reduced CD 324 of the deposition layer feature 322 is at least 10% less than the CD 316 of the mask feature (i.e. not greater than 90% of the CD 316 of the mask feature). More preferably, the reduced CD 324 of the deposition layer feature 322 is at least 20% less than the CD 316 of the mask feature (i.e. not greater than 80% of the CD 316 of the mask feature). Most preferably, the reduced CD 324 of the deposition layer feature 322 is at least 30% less than the CD 316 of the mask feature (i.e. not greater than 70% of the CD 316 of the mask feature). For example, the deposition layer feature may have a reduced CD 316 that is 99% less than the CD 316 of the mask feature. It is also desirable that the deposition layer feature 322 has substantially vertical sidewalls 328, which are highly conformal as shown. An example of a substantially vertical sidewall is a sidewall that from bottom to top makes an angle of between 88° to 90° with the bottom of the feature. Conformal sidewalls have a deposition layer that has substantially the same thickness from the top to the bottom of the feature. Non-conformal sidewalls may form a faceting or a bread-loafing formation, which provide non-substantially vertical sidewalls. Tapered sidewalls (from the faceting formation) or bread-loafing sidewalls may increase the deposition layer CD and provide a poor etching mask. Preferably, the deposition on the side wall is thicker than the deposition on the bottom of the mask feature. More preferably, no layer is deposited over the bottom of the mask feature.

In some embodiments of the invention, none of the deposition layer is on top of the etch mask. In other embodiments, part of the deposition layer is formed over the top of the etch mask.

Features are then etched into the layer to be etched 308 through the deposition layer features 322 (step 212). FIG. 3C shows a feature 332 etched into the layer to be etched 308. In this example, the feature 332 etched in the layer to be etched 308 has a CD 336, which is equal to the CD 324 of the deposition layer feature 322. In practice, the CD 336 of the feature 332 may be slightly larger than the CD 324 of the feature 322 of the deposition layer 320. However, since the CD 324 of the deposition layer feature 322 is significantly smaller than the CD 316 of the mask 312, the CD 336 of the feature 332 in the layer to be etched 308 is still smaller than the CD 316 of the mask 312. If the CD 324 of the deposition layer was only slightly smaller than the CD of the mask, or if the deposition layer was faceted or bread loafed, then the CD of the layer to be etched might not be smaller than the CD of the mask. In addition, a faceted or bread-loafing deposition layer may cause a faceted or irregularly shaped feature in the layer to be etched. It is also desirable to minimize deposition on the bottom of the mask feature. Preferably, the CD 336 of the feature 332 etched in the layer to be etched 308 is at least 30% less than the CD 316 of the mask feature. More preferably, the CD 336 of the feature 332 etched in the layer to be etched 308 is at least 40% less than the CD 316 of the mask feature. Most preferably, the CD 336 of the feature 332 etched in the layer to be etched 308 is at least 50% less than the CD 316 of the mask feature. The mask and deposition layer may then be removed (step 216). This may be done as a single step or two separate steps with a separate deposition layer removal step and mask removal step. Ashing may be used for the stripping process. FIG. 3D shows the stack 300 after the deposition layer and etch mask have been removed. Additional formation steps may be performed (step 220). For example, a contact 340 may then be formed in the feature. To provide a dual damascene structure, a trench may be etched before the contact is formed. Additional processes may be performed after the contact is formed.

Due to the nature of a vapor phase deposition method, formation of a conformal layer 320 is always difficult since deposition rate invariably favors the top portion of the profile because of the line of sight leading to formation of a bread-loaf shape of the deposition layer and in the extreme a pinch-off at the profile top. Methods used to obtain a more vertical profile, such as a thermal “re-flow” post deposition, often lead to other undesirable side-effects.

One advantage of the inventive process is that a non-vertical deposition profile can be made more vertical by the subsequent anisotropic etch step. Another advantage of the inventive process is that deposition layers may be added and etch back resulting in a thin deposition layer formed during each cycle. Such a thin later can help to prevent delamination, which can be caused by forming a single thick layer. A single thick film may also cause other problems. In addition the cyclical process provides more control parameters, which allow for more tuning parameters, to provide a better conformal deposition layer. Since the cyclic process will keep the bread-loaf at a minimum throughout the CD reduction process, the CD gains at the bottom portion of the deposition profile can keep growing.

### Example of Dielectric Etch

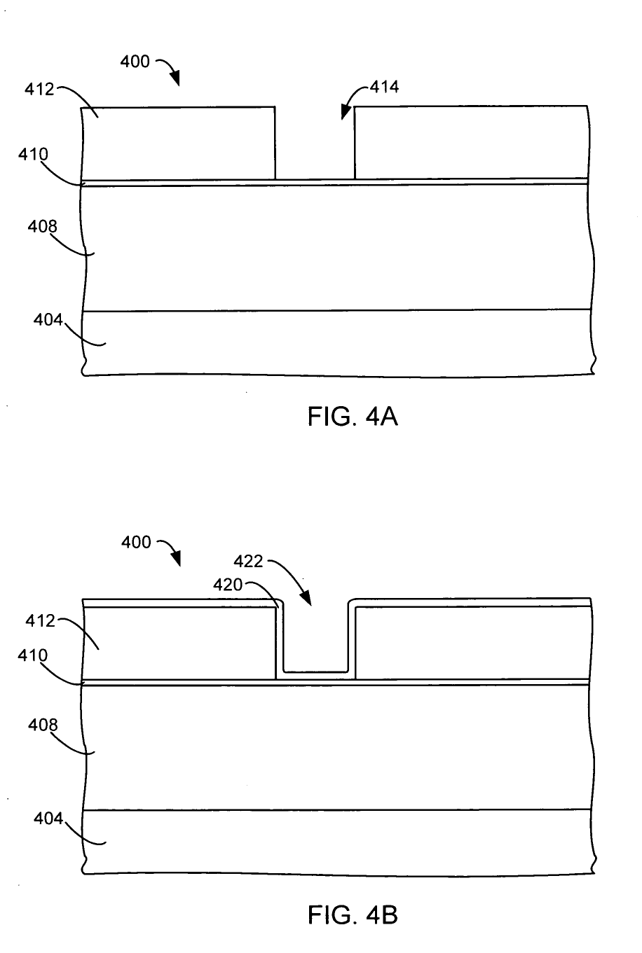

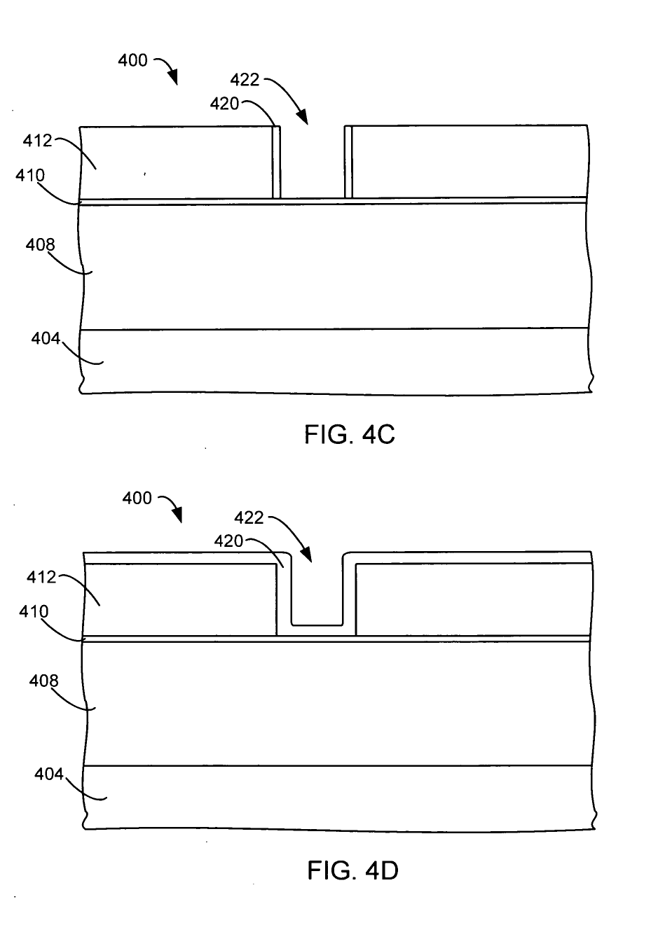

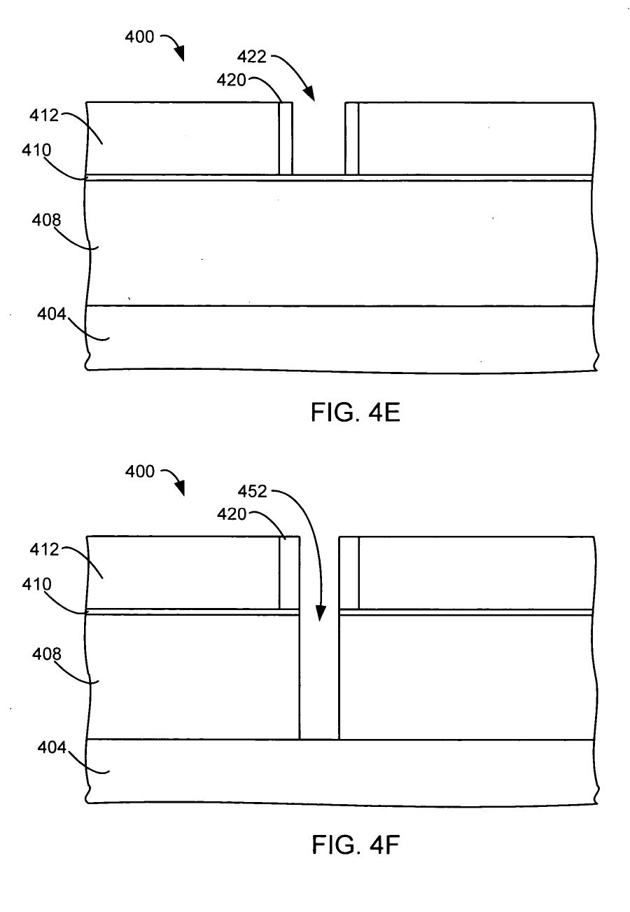

In an example of the invention, a layer to be etched is a dielectric layer 408, which is placed over a substrate 404, as shown in FIG. 4A. An antireflective layer (ARL) 410 is placed over the dielectric layer 408. A patterned photoresist mask 412 of 248 nm photoresist is placed over the ARL 410 (step 204). A photoresist mask feature 414 is formed in the patterned photoresist mask 412. Presently, for 248 nm photoresist etch mask a typical CD for the photoresist may be 230-250 nm, using conventional processes. The substrate is placed in a plasma processing chamber.

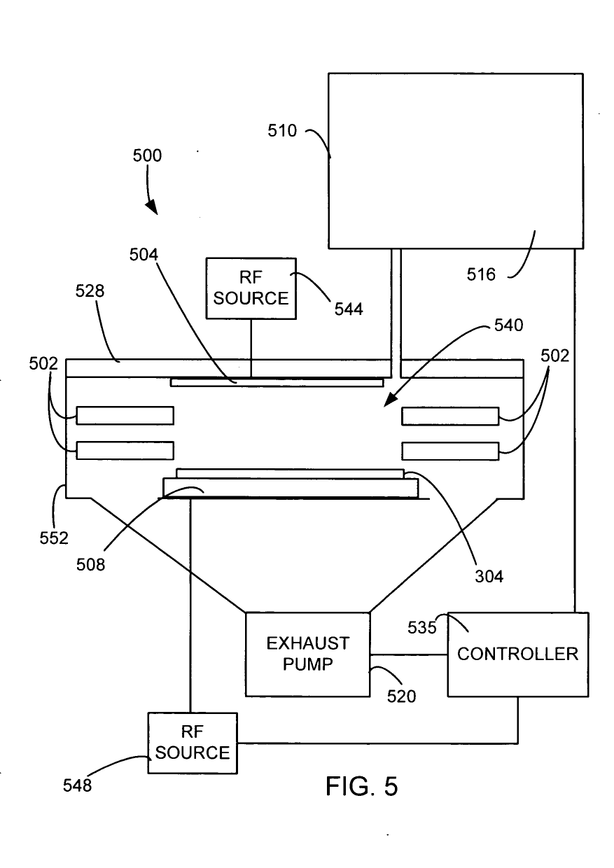

FIG. 5 is a schematic view of a plasma processing chamber 500 that may be used for performing the CD reduction, etching, and stripping. The plasma processing chamber 500 comprises confinement rings 502, an upper electrode 504, a lower electrode 508, a gas source 510, and an exhaust pump 520. Within plasma processing chamber 500, the substrate 404 is positioned upon the lower electrode 508. The lower electrode 508 incorporates a suitable substrate chucking mechanism (e.g., electrostatic, mechanical clamping, or the like) for holding the substrate 304. The reactor top 528 incorporates the upper electrode 504 disposed immediately opposite the lower electrode 508. The upper electrode 504, lower electrode 508, and confinement rings 502 define the confined plasma volume. Gas is supplied to the confined plasma volume by the gas source 510 and is exhausted from the confined plasma volume through the confinement rings 502 and an exhaust port by the exhaust pump 520. A first RF source 544 is electrically connected to the upper electrode 504. A second RF source 548 is electrically connected to the lower electrode 508. Chamber walls 552 surround the confinement rings 502, the upper electrode 504, and the lower electrode 508. Both the first RF source 544 and the second RF source 548 may comprise a 27 MHz power source and a 2 MHz power source. Different combinations of connecting RF power to the electrode are possible. In the case of Exelan HPT™, which is basically the same as an Exelan HP with a Turbo Pump attached to the chamber, made by LAM Research Corporation™ of Fremont, Calif., which may be used in a preferred embodiment of the invention, both the 27 MHz and 2 MHz power sources make up the second RF power source 548 connected to the lower electrode, and the upper electrode is grounded. A controller 535 is controllably connected to the RF sources 544, 548, exhaust pump 520, and the gas source 510. The Exelan HPT would be used when the layer to be etched 308 is a dielectric layer, such as silicon oxide or organo silicate glass.

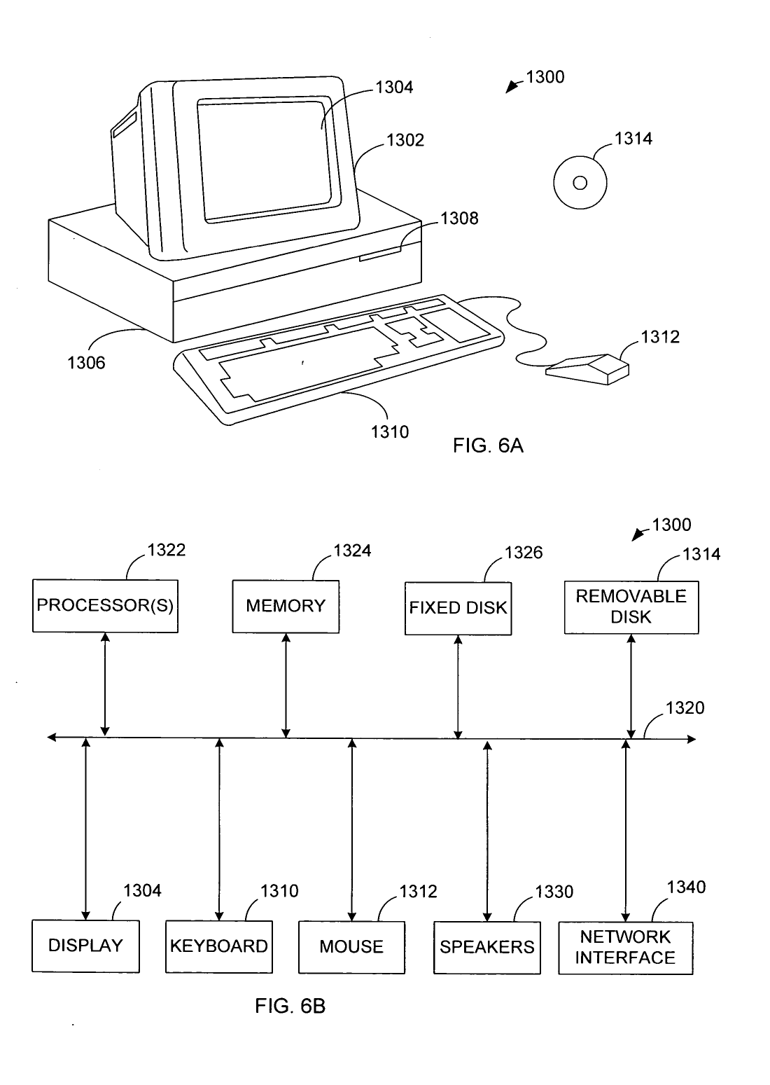

FIGS. 6A and 6B illustrate a computer system 1300, which is suitable for implementing a controller 535 used in embodiments of the present invention. FIG. 6A shows one possible physical form of the computer system. Of course, the computer system may have many physical forms ranging from an integrated circuit, a printed circuit board, and a small handheld device up to a huge super computer. Computer system 1300 includes a monitor 1302, a display 1304, a housing 1306, a disk drive 1308, a keyboard 1310, and a mouse 1312. Disk 1314 is a computer-readable medium used to transfer data to and from computer system 1300.

FIG. 6B is an example of a block diagram for computer system 1300. Attached to system bus 1320 is a wide variety of subsystems. Processor(s) 1322 (also referred to as central processing units, or CPUs) are coupled to storage devices, including memory 1324. Memory 1324 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 1326 is also coupled bi-directionally to CPU 1322; it provides additional data storage capacity and may also include any of the computer-readable media described below. Fixed disk 1326 may be used to store programs, data, and the like and is typically a secondary storage medium (such as a hard disk) that is slower than primary storage. It will be appreciated that the information retained within fixed disk 1326 may, in appropriate cases, be incorporated in standard fashion as virtual memory in memory 1324. Removable disk 1314 may take the form of any of the computer-readable media described below.

CPU 1322 is also coupled to a variety of input/output devices, such as display 1304, keyboard 1310, mouse 1312 and speakers 1330. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 1322 optionally may be coupled to another computer or telecommunications network using network interface 1340. With such a network interface, it is contemplated that the CPU might receive information from the network, or might output information to the network in the course of performing the above-described method steps. Furthermore, method embodiments of the present invention may execute solely upon CPU 1322 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

Other examples may use other devices to carry out the invention.

Next, the cyclical critical dimension reduction is performed to provide deposition layer features with reduce the CD (step 208). In this example, the deposition phase (step 209) comprises providing a deposition gas and generating a plasma from the deposition gas to form a deposition layer. In this example, the deposition gas comprises a polymer forming recipe. An example of such a polymer forming recipe is a hydrocarbon gas such as, CH₄ and C₂H₄, and a fluorocarbon gas, such as CH₃F, CH₂F₂, CHF₃, C₄F₆, and C₄F₈. Another example of a polymer forming recipe would be a fluorocarbon chemistry and a hydrogen containing gas, such as a recipe of CF₄ and H₂. In a preferred embodiment, CF₄ and H₂ have a molar ratio (CF₄:H₂) in the range of 1:2 to 2:1. In this example, power is supplied at 400 watts at 2 MHz and 800 watts at 27 MHz. FIG. 4B is a schematic cross-sectional view of a deposition layer 420 formed over the photoresist mask 412, by the deposition phase (step 209). In this example, part of the deposition layer 420 is over the top surface of the photoresist 412 and over parts of the exposed ARL 410 at the bottom of the mask features, in addition to being over the sidewall of the photoresist 412.

The etch phase (step 210) comprises providing an etch phase gas and generating an etch phase plasma from the etch phase gas to etch away part of the deposition layer 420. The etch phase gas is different from the deposition gas. As illustrated, the deposition phase (step 209) and the etch phase (step 210) occur at different times. Preferably, the etch is an anisotropic etch. In this example the etch gas comprises a fluorocarbon chemistry, such as CF₄, CHF₃, and CH₂F₂. Other additives such as O₂, N₂, and H₂ may be added. In this example, power is supplied at 0 watts at 2 MHz and 800 watts at 27 MHz. FIG. 4C is a schematic cross-sectional view of the deposition layer 420 formed over the photoresist mask 412 after of the deposition layer has been etched away by the etch phase (step 210). In this example, the etch phase (step 210) thins and removes the parts of the deposition layer 420 over the top surface of the photoresist 412 and over parts of the exposed ARL 410, as shown.

In this example, the deposition phase (step 209) is repeated a second time. The same deposition recipe is used here as described above. In alternative embodiments, the deposition recipe can also be modified from the recipe in the first deposition phase. FIG. 4D is a schematic cross-sectional view of a deposition layer 420 formed over the photoresist mask 412, by the second deposition phase (step 208). Again, part of the deposition layer 420 is over the top surface of the photoresist 412 and over parts of the exposed ARL 410, in addition to being over the sidewall of the photoresist 412. The selective etching in this embodiment, allows the net deposition on the sidewall to be thicker due to the remaining deposition on the sidewall after the previous etch.

The etch phase (step 210) is repeated a second time. The same etch recipe is used here as described above. The etch recipe can also be modified from the recipe in the first deposition phase. FIG. 4E is a schematic cross-sectional view of the deposition layer 420 formed over the photoresist mask 412, after part of the deposition layer 420 has been etched away by the second etch phase (step 210). Again, the etch phase (step 210) removes part of the deposition layer 420 over the top surface of the photoresist 412 and over parts of the exposed ARL 410, as shown. As can be seen, the remaining deposition layer over the sidewalls is thicker than the remaining deposition layer over the sidewalls shown in FIG. 4C.

The cyclical critical dimension process (step 208) can repeat these cycles as many times as possible until the desired critical dimension reduction is reached.

After the cyclical critical dimension reduction (step 208) is completed, the dielectric layer is then etched using the etch mask with the reduced CD (step 212). The etch comprises providing an etch gas and forming an etch plasma from the etch gas. In this example a different etch recipe is used for the dielectric layer etch (step 212) than the etch recipe used in the etch phase (step 210) or the recipe in the deposition phase (step 209). This is because it is desirable that the dielectric layer 408 is not etched during the cyclical critical dimension reduction (step 208). An example of an etch chemistry for etching the dielectric layer would be C₄F₆ with O₂ or N₂. FIG. 4F is a cross sectional view of the dielectric layer 408, after the feature 452 has been etched in the dielectric layer 408. The critical dimension of the feature 452 etched into the dielectric layer 408 is smaller than the critical dimension of original photoresist mask feature.

The etch mask is then removed (step 216). In this example a standard photoresist strip is used to remove the etch mask. Additional formation steps may also be performed (step 220).

Preferably, each deposition layer for each deposition phase is between 1 to 100 nm. More preferably, each deposition layer for each deposition phase is between 1 to 50 nm. Most preferably, each deposition layer for each deposition phase is between 1 to 10 nm. As a result, each deposition layer would have a thickness between the thickness of a typical bottom antireflective coating (BARC) to about a quarter of the thickness of the reduction of CD, so that the desired reduction in CD may be performed in two cycles. Preferably, the cyclical critical dimension reduction is performed in at least two cycles. More preferably, the critical dimension reduction is performed in at least five cycles.

The invention is useful for reducing CD for features that are either trenches or holes.

In different embodiments of the inventions, the etch layer may be a dielectric layer, such as a low-k dielectric layer or a metal containing layer. The etch layer may also be a hardmask layer, such as amorphous carbon or a SiN layer that serves as a hardmask for the later etching of a feature.

In other embodiments of the invention, the temperature of the wafer is kept below glass transition temperature of the photoresist materials to avoid distortion of the photoresist mask features. Preferably, the wafer temperature is kept in the range from 100 C to −100 C. More preferably, the temperature is kept in the range of 80 C to −80 C. Most preferably, the temperature is maintained in the range of 40 C to −40 C.

Since the deposited material is most likely of properties different from the photoresist materials, excessive accumulation of the deposited materials on top of the photoresist layer can cause undesirable distortion of the photoresist features. By doing the deposition and etch process in more than five cycles, it is possible to avoid excessive accumulation of the deposited material buildup during any time in the CD reduction process.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for forming features in an etch layer in an etch stack with an etch mask over the etch layer, wherein the etch mask has etch mask features with sidewalls, where the etch mask features have a first critical dimension, comprising
performing a cyclical critical dimension reduction to form deposition layer features with a second critical dimension, which is less than the first critical dimension, wherein each cycle, comprises:
a depositing phase for depositing a deposition layer over the exposed surfaces, including the vertical sidewalls, of the etch mask features; and
an etching phase for etching back the deposition layer leaving a selective deposition on the vertical sidewalls; and
etching features into the etch layer, wherein the etch layer features have a third critical dimension, which is less than the first critical dimension.

2. The method, as recited in claim 1, wherein the cyclical critical dimension reduction is performed for at least two cycles.

3. The method, as recited in claim 1, wherein the cyclical critical dimension reduction is performed for at least five cycles.

4. The method, as recited in claim 3, wherein the etching phase does not etch the etch layer.

5. The method, as recited in claim 3, wherein the performing the critical dimension reduction forms substantially vertical deposition sidewalls.

6. The method, as recited in claim 3, wherein the second critical dimension is less than 70% of the first critical dimension.

7. The method, as recited in claim 3, wherein the third critical dimension is less than 70% of the first critical dimension.

8. The method, as recited in claim 3, wherein the etch mask is a photoresist mask, further comprising stripping the photoresist mask and the deposition layer.

9. The method, as recited in claim 8, wherein the stripping the photoresist mask and deposition layer comprises ashing the photoresist mask and deposition layer.

10. The method, as recited in claim 9, wherein the depositing phase deposits part of the deposition layer on bottoms of the etch mask features and on a top surface of the etch mask.

11. The method, as recited in claim 10, wherein the etching phase at least partially removes the deposition layer on bottoms of the etch mask features.

12. The method, as recited in claim 10, wherein the photoresist mask is formed from 248 nm photoresist and the etch layer feature has a CD not greater than 140 nm.

13. The method, as recited in claim 11, wherein the third critical dimension is less than 70% of the first critical dimension.

14. The method, as recited in claim 1, wherein the depositing phase, etching phase, and the etching features into the etch chamber are done in the same etch chamber.

15. The method, as recited in claim 1, wherein the depositing phase, etching phase, and the etching features into the etch chamber are performed at separate times, so that none of these processes are performed at the same time.

16. The method, as recited in claim 1, wherein the depositing phase, comprises:
providing a depositing gas; and
forming a depositing plasma from the depositing gas.

17. The method, as recited in claim 1, wherein the etching phase, the etching process is anisotropic.

18. The method, as recited in claim 17, wherein the etching plasma contains at least one of fluorocarbons and O₂.

19. The method, as recited in claim 17, wherein the etching plasma contains at least one of CF₄ and O₂.

20. The method, as recited in claims 16, wherein the depositing gas contains at least one of a hydrocarbon and a fluorocarbons.

21. The method, as recited in claims 16, wherein the depositing gas contains at least both of CF₄ and H₂.

22. The method, as recited in claims 21, wherein CF₄ and H₂ have a molar ratio (CF₄:H₂) in the range of 1:2 to 2:1.

23. The method, as recited in claim 16, wherein the etching phase, comprises:
providing an etching phase gas, which is different from the depositing gas; and
forming an etching phase plasma from the etching phase gas.

24. The method, as recited in claim 23, wherein the etching features into the etch layer, comprises
providing an etching gas, which is different than the etching phase gas and the depositing gas; and
forming an etching plasma from the etching gas.

25. The method, as recited in claim 24, wherein the depositing phase gas is a polymer forming gas.

26. A semiconductor device formed by the method of claim 1.

27. An apparatus for performing the method of claim 1.

28. A method for forming a feature in an etch layer, comprising:
placing an etch stack with an etch layer into an etch chamber, wherein an etch mask with etch mask features with sidewalls is over the etch layer, where the etch mask features have a first critical dimension;
performing for at least two cycles a cyclical critical dimension reduction to form deposition layer features with a second critical dimension, which is less than the first critical dimension, within the etch chamber, wherein each cycle comprises:
a depositing phase for depositing a deposition layer over the sidewalls of the etch mask features; and
an etching phase for etching back the deposition layer; and
etching features into the etch layer within the etch chamber, wherein the etch layer features have a third critical dimension, which is less than the first critical dimension.

29. An apparatus for forming a features in an etch layer, wherein the layer is supported by a substrate and wherein the etch layer is covered by an etch mask with mask features with a first CD, comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet,
a controller controllably connected to the gas source and the at least one electrode, comprising:
at least one processor; and
computer readable media, comprising:
computer readable code for providing for at least five cycles a cyclical critical dimension reduction process to form deposition layer features with a second critical dimension, comprising:
computer readable code for providing a flow of a deposition gas to the plasma processing chamber enclosure;
computer readable code for stopping the flow of the deposition gas to the plasma processing chamber enclosure;
computer readable code for providing a flow of an etch phase gas to the plasma processing chamber enclosure after the flow of the first deposition gas is stopped; and
computer readable code for stopping the flow of the etch phase gas to the plasma processing chamber enclosure; and
computer readable code for providing a flow of an etchant gas to the plasma processing chamber after completion of the at least five cycles of the cyclical critical dimension reduction process; and
computer readable code for etching features in the etch layer, using the etchant gas wherein the features in the layer have a third critical dimension.
